(19) United States
(12) Patent Application Publication
(10) Pub. No.: US 2018/0196321 A1
(43) Pub. Date: Jul. 12, 2018

(54) DISPLAY SUBSTRATE AND LIQUID CRYSTAL DISPLAY APPARATUS

(71) Applicant: BOE TECHNOLOGY GROUP CO., LTD., Beijing (CN)

(72) Inventor: Zheng FANG, Beijing (CN)

(73) Assignee: BOE TECHNOLOGY GROUP CO., LTD., Beijing (CN)

(21) Appl. No.: 15/562,975

(22) PCT Filed: Feb. 17, 2017
(86) PCT No.: PCT/CN2017/073859

§ 371 Date: Sep. 29, 2017

(30) Foreign Application Priority Data
Apr. 15, 2016 (CN) 201620320070.X

(51) Int. Cl. G02F 1/1362; G02F 1/1343; H01L 27/32

(52) U.S. Cl. CPC G02F 1/136286; G02F 2001/134345; H01L 27/3276; G02F 1/134336

(57) ABSTRACT

A display substrate and a liquid crystal display apparatus are provided. The display substrate includes a plurality of data lines, a plurality of gate lines and a plurality of pixel units. At least one of the pixel units at least includes two sub-pixel electrodes insulated from each other and two thin film transistors; the two sub-pixel pixels are respectively connected to different thin film transistors, and source electrodes of the two thin film transistors are respectively connected with two different data lines.

### TECHNICAL FIELD

Embodiments of the present disclosure relate to a technical field of display, and particularly, to a display substrate and a liquid crystal display apparatus.

### BACKGROUND

Currently, methods for improving a display effect of a display apparatus include a Multi-domain Vertical Alignment (MVA) technology, an In-Plane Switching (IPS) technology, a Fringe Field Switching (FFS) technology and the like. In recent years, an FFS mode is widely applied to a high-end product with a high resolution by means of advantages thereof in the aspects of a penetration rate, a driving voltage, a wide viewing angle, touch ability and the like, and gradually becomes a main trend.

However, when the FFS mode is adopted, a display image generally will be flickered. When a voltage of a reference electrode on a common electrode is deviated, intensity of an electric field between a pixel electrode and the reference electrode is changed so as to cause difference in deflection of liquid crystal molecules and influence on light transmittance. Such change of the light transmittance, which is caused by change of a voltage difference between the pixel electrode and the reference voltage, will enable the display image to be flickered, resulting in influence on the display effect. Meanwhile, due to existence of a flexoelectric effect, when the pixel electrode is applied with positive and negative polar voltages, brightness of the display image will be different. Under the drive of the positive and negative polar voltages, pixel points are different in brightness, and thus, along with reversal of a polarity, the image will be flickered in an alternatively dark and bright mode.

### SUMMARY

At least one embodiment of the present disclosure relates to a display substrate and a display apparatus, which can solve a problem of a flickering phenomenon of a display image.

One aspect of the disclosure provides a display substrate, comprising a plurality of data lines, a plurality of gate lines and a plurality of pixel units, wherein at least one of the pixel units at least includes two sub-pixel electrodes insulated from each other and two thin film transistors; and the two sub-pixel pixels are respectively connected to different thin film transistors in the two thin film transistors, and source electrodes of the two thin film transistors are respectively connected with two different data lines.

For example, the two different data lines are configured to apply voltages with opposite polarities.

For example, the two sub-pixel electrodes are respectively positioned in two different regions in the pixel unit.

For example, the two sub-pixel electrodes are sequentially arranged in an extension direction of the gate lines.

For example, the two sub-pixel electrodes are sequentially arranged in an extension direction of the data lines.

For example, gate electrodes of the two thin film transistors are connected to a same gate line or are respectively connected to two different gate lines.

For example, an interval distance of the two sub-pixel electrodes is 8 to 10 μm.

For example, the two sub-pixel electrodes include plate electrodes or strip electrodes.

For example, the at least one pixel unit includes three sub-pixel electrodes which are not in contact with one another and includes three thin film transistors respectively connected with the three sub-pixel electrodes; and source electrodes of the three thin film transistors are respectively connected with different data lines.

For example, the at least one pixel unit includes four sub-pixel electrodes which are not in contact with one another and includes four thin film transistors respectively connected with the four sub-pixel electrodes; and source electrodes of the four thin film transistors are respectively connected with different data lines.

For example, the two different data lines are configured to apply voltages with a same absolute value.

Another aspect of the disclosure provides a liquid crystal display apparatus, comprising the display substrate as mentioned above.

For example, the liquid crystal display apparatus further comprises a color filter substrate opposite to the display substrate, the color filter substrate including pixel units respectively corresponding to the plurality of pixel units of the display substrate, and each pixel unit of the color filter substrate including a color filter of one color.

Another aspect of the disclosure provides a driving method of the liquid crystal display apparatus as mentioned above, comprising: applying voltages to different sub-pixel electrodes of each pixel unit on the display substrate, wherein the voltages applied to different sub-pixel electrodes of each pixel unit are opposite in polarity and equal in absolute value.

### BRIEF DESCRIPTION OF THE DRAWINGS

In order to clearly illustrate the technical solution of the embodiments of the invention, the drawings of the embodiments will be briefly described in the following; it is obvious that the described drawings are only related to some embodiments of the invention and thus are not limitative of the invention.

FIG. 1 is a top-view schematic diagram of a pixel unit structure;

FIG. 2a is a schematic diagram in which two sub-pixel electrodes in one pixel unit, which are arranged along an extension direction of a gate line, are connected to the same gate line according to an embodiment of the present disclosure;

FIG. 2b is a schematic diagram in which two sub-pixel electrodes in one pixel unit, which are arranged along an extension direction of gate lines, are connected to different gate lines according to an embodiment of the present disclosure;

FIG. 3 is a schematic diagram in which source and drain electrodes of a Thin Film Transistor (TFT) are arranged on a gate line according to an embodiment of the present disclosure;

FIG. 4 is a schematic diagram in which two sub-pixel electrodes in one pixel unit, which are arranged along an extension direction of data lines, are connected to different gate lines according to an embodiment of the present disclosure;

FIG. 5 is a schematic diagram in which a gate line in part of a display region drives sub-pixel electrodes which are positioned on both sides of the gate line and close to the gate line according to an embodiment of the present disclosure;

FIG. 6 is a schematic diagram of a distance between two sub-pixel electrodes in a pixel unit according to an embodiment of the present disclosure.

### DETAILED DESCRIPTION

In order to make objects, technical details and advantages of the embodiments of the invention apparent, the technical solutions of the embodiment will be described in a clearly and fully understandable way in connection with the drawings related to the embodiments of the invention. It is obvious that the described embodiments are just a part but not all of the embodiments of the invention. Based on the described embodiments herein, those skilled in the art can obtain other embodiment(s), without any inventive work, which should be within the scope of the invention.

For example, a display substrate for a liquid crystal display apparatus includes a plurality of gate lines and a plurality of data lines, which intersect with each other. The gate lines and data lines define a plurality of pixel units arranged in an array on the display substrate. Each pixel unit includes a pixel electrode, a corresponding Thin Film Transistor (TFT) and the like. By controlling change of a voltage difference between the pixel electrode and a common electrode in each pixel unit, liquid crystal molecules in the liquid crystal display apparatus can be controlled to be deflected at different angles so as to control light transmittance and complete image display.

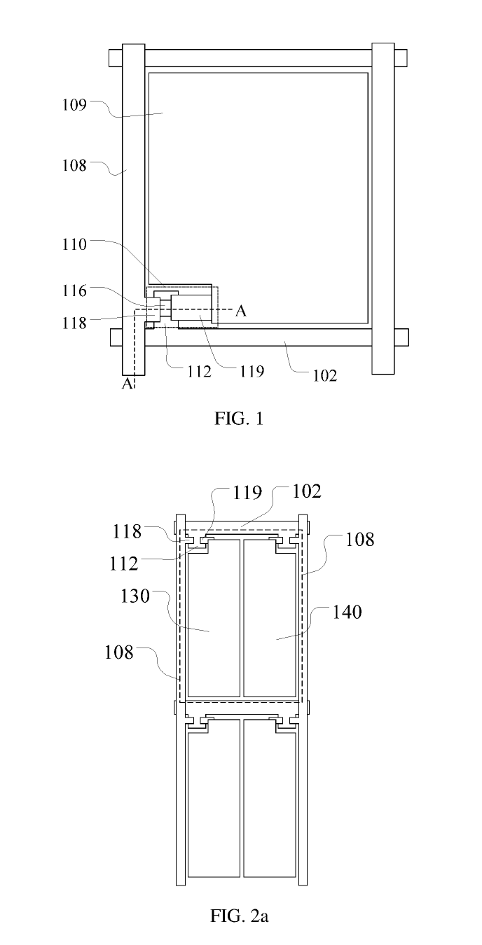

FIG. 1 is a top-view schematic diagram of a pixel unit of a display substrate. With reference to FIG. 1, a gate line 102 and a data line 108 define one pixel unit, a TFT 110 is arranged near an intersection region of the gate line 102 and the data line 108, and the TFT includes a gate electrode 112, a source electrode 118, a drain electrode 119 and an active layer 116 which is arranged on the gate electrode 112 and is used for providing a channel for the source electrode 118 and the drain electrode 119. The gate line 102 is connected with the gate electrode 112 so as to provide a gate line scanning signal; the source electrode 118 is connected with the data line 108 so as to provide a data signal; and the drain electrode 119 is connected with a pixel electrode 109, is used as an output electrode of the TFT and charges the pixel electrode 109. In such pixel structure, when positive and negative voltages are adopted to drive, if a reference voltage set on a common electrode is deviated, a flickering phenomenon of a display image will be generated so as to influence a display effect. In addition, even though the reference voltage is not deviated, such driving reverse in polarity of the positive and negative voltages will also cause flickering of the image.

In one aspect, the present disclosure provides a display substrate. The display substrate includes a plurality of data lines, a plurality of gate lines and a plurality of pixel units; at least one of the plurality of pixel units at least includes two sub-pixel electrodes insulated from each other and two thin film transistors; and the two sub-pixel electrodes are respectively connected to different thin film transistors, and source electrodes of the two thin film transistors are respectively connected with two different data lines. Such pixel electrode structure can ensure that positive and negative voltage driving simultaneously exists in the same pixel unit, so as to ensure that even though polarities of driving voltages are reverse, brightness of the same pixel unit cannot have differences, thereby reducing flickering of a display apparatus.

According to the present disclosure, by arranging two or more sub-pixel electrodes insulated from each other in one pixel unit and respectively configuring one TFT to each sub-pixel electrode, positive and negative voltage driving in one pixel unit is implemented. For example, the voltages of two data lines connected with two sub-pixel electrodes are opposite in polarity. Such structure of the sub-pixel electrodes driven by the positive and negative voltages in one pixel unit can eliminate the image flickering phenomenon generated when a positive voltage or negative voltage is separately adopted to drive.

It should be noted that the source electrode and the drain electrode of the TFT are not strictly distinguished, and when connection modes between the source and drain electrodes and the data line as well as the pixel electrode are interchanged, names of the source and drain electrodes are also interchanged accordingly. Those skilled in the art should not make restricted explanation thereto.

In addition, the pixel units do not always correspond to lattices formed by mutual intersection of the plurality of gate lines and the plurality of data lines, as long as the pixel units are positioned in a display region, and those skilled in the art should not make restricted explanation thereto.

In one embodiment, two sub-pixel electrodes in a pixel unit of the embodiment of the present disclosure are positioned in different regions of the pixel unit, e.g., two side-by-side regions in the pixel unit. For example, no intersectional portion exists between the two sub-pixel electrodes. Therefore, a case of generating an electric field between two sub-pixel electrodes to influence the display effect when the two sub-pixel electrodes are subjected to positive and negative voltage driving is prevented.

By taking a case of providing one pixel unit and arranging two sub-pixel electrodes and two TFTs in the pixel unit as an example, a connection relationship between the TFTs of the sub-pixel electrodes in the pixel unit according to the present disclosure and the gate lines as well as the data lines will be further illustrated. However, according to the present disclosure, the number of the sub-pixel electrodes in the pixel unit is not limited to two.

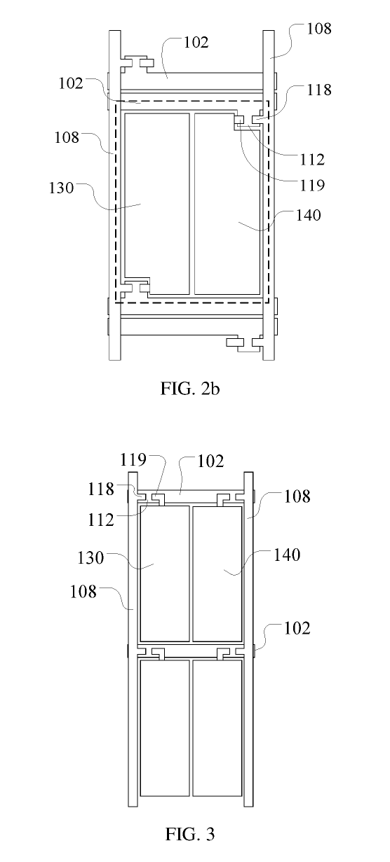

In one embodiment of the present disclosure, the number of sub-pixel electrodes in one pixel unit, for example, is two, and two sub-pixel electrodes are positioned in two different regions in the pixel unit. For example, two sub-pixel electrodes are arranged side by side along an extension direction of the gate line. With reference to FIG. 2a, in the pixel unit (shown as a dotted line in the drawing), the sub-pixel electrode 130 and the sub-pixel electrode 140 are set to be sequentially arranged along the extension direction of the gate line 102 and be side by side mutually. Each sub-pixel electrode is respectively driven by one TFT. The gate electrodes 112 of two TFTs are connected with the same gate line 102. The source electrodes 118 of two TFTs are respectively connected with two data lines 108 (i.e., the data lines 108 on the left side and the right side of the pixel unit in the drawing) which define the pixel unit and are adjacent to each other. The drain electrodes 119 of two TFTs are respectively connected with the sub-pixel electrode 130 and the sub-pixel electrode 140. For example, when the sub-pixel electrode 130 and the sub-pixel electrode 140 are respectively configured to be applied with positive and negative data voltages by two TFTs, image flickering of the display apparatus under the positive and negative voltage drive can be eliminated. For example, the sub-pixel electrode 130 and the sub-pixel electrode 140 correspond to the same pixel point in the same display image, absolute values of data voltages applied to the sub-pixel electrode 130 and the sub-pixel electrode 140 are equal, but the data voltages respectively are a positive value and a negative value. By adopting one gate line to drive two TFTs in the pixel unit, energy consumption can be reduced, and an aperture rate can be improved.

In the embodiment, the gate electrodes 112 of the TFTs of the sub-pixel electrode 130 and the sub-pixel electrode 140 can be respectively connected with two gate lines 102 which define the pixel unit and are adjacent to each other. With reference to FIG. 2b, as previously mentioned, in the pixel unit (shown as the dotted line in the drawing), the source electrodes 118 of two TFTs are respectively connected with two data lines 108 which define the pixel unit and are adjacent to each other. The drain electrodes 119 of two TFTs are respectively connected with the sub-pixel electrode 130 and the sub-pixel electrode 140. The gate electrodes 112 of two TFTs are respectively connected with two adjacent gate lines 102 (i.e., the gate lines 102 on the upper side and the lower side of the pixel unit in the drawing). By adopting different gate lines to provide gate signals for different sub-pixel electrodes, flexibility of TFT control can be improved, and complete damage to the pixel electrodes when one single gate line is damaged can be prevented, i.e., a certain redundancy capacity is given to the pixel unit. For example, the two gate lines 102 are synchronously applied with on and off signals.

In the embodiment, for example, the source electrode and the drain electrode of the TFT can be both arranged on the gate line. With reference to FIG. 3, the source electrodes 118 and the drain electrodes 119 of two TFTs are all arranged on the gate lines 102, i.e., one portion of the gate line 102 is used as the gate electrode of the TFT, and correspondingly, an active layer of the TFT is also overlapped with the portion used as the gate electrode. Namely, orthographic projections of the source electrodes 118 and the drain electrodes 119 of two TFTs on one main surface (e.g., an upper surface or a lower surface) of the substrate are at least partially positioned in orthographic projections of the gate lines 102 connected with the TFTs on the main surface of the substrate, and for example, the orthographic projections of the source electrodes 118 and the drain electrodes 119 of two TFTs on one main surface of the substrate are completely positioned within the orthographic projections of the gate lines 102 connected with the TFTs on the main surface of the substrate, so as to promote the aperture ratio of the pixel electrode and improve display brightness. With further reference to FIG. 3, as previously mentioned, the source electrodes 118 of two TFTs are respectively connected with two data lines 108 which define the pixel unit and are adjacent to each other. The drain electrodes 119 of two TFTs are respectively connected with the sub-pixel electrode 130 and the sub-pixel electrode 140. The gate electrodes 112 of two TFTs are respectively connected to the same gate line 102. For example, for the structure that the gate electrodes of the TFTs of two sub-pixel electrodes are connected with different gate lines, the source electrodes and the drain electrodes of the TFTs can also be arranged on the gate lines connected with the TFTs so as to promote the aperture ratio of the pixel electrode and improve display brightness.

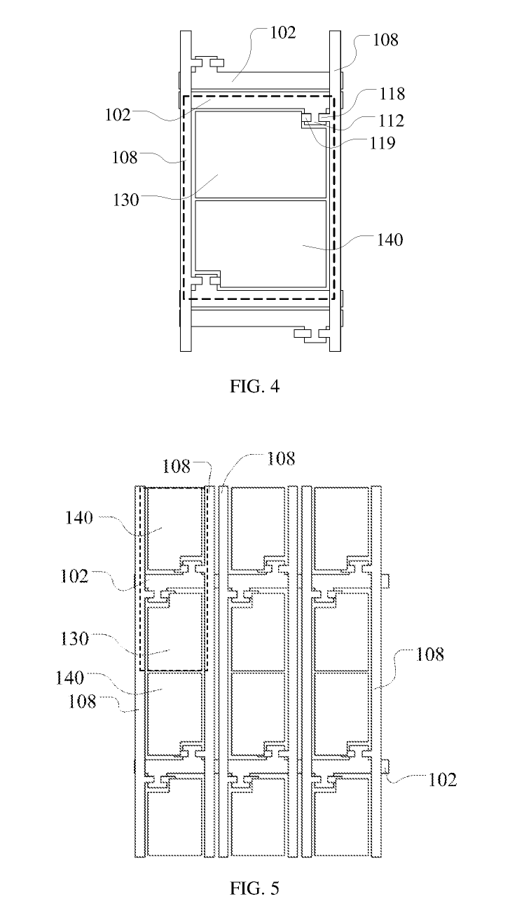

In one embodiment of the present disclosure, the number of the sub-pixel electrodes, for example, is two, and the two sub-pixel electrodes are set to be arranged side by side along the extension direction of the data line. With reference to FIG. 4, FIG. 4 shows that the sub-pixel electrodes 130 and 140 in the pixel unit (shown as the dotted line in the drawing) are sequentially arranged along the extension direction of the data line 108, and are side by side mutually. As previously mentioned, each of the sub-pixel electrode 130 and the sub-pixel electrode 140 is respectively driven by one TFT. The gate electrodes of the TFTs of two sub-pixel electrodes are respectively connected with the respectively adjacent gate lines 102 (i.e., in the drawing, the sub-pixel electrode 130 is connected with the gate line positioned on the upper side of the sub-pixel electrode 130, and the sub-pixel electrode 140 is connected with the gate line positioned on the lower side of the sub-pixel electrode 140). With further reference to FIG. 4, the source electrodes 118 of the two TFTs are respectively connected with two data lines 108 (i.e., the data lines 108 on the left side and the right side of the pixel unit in the drawing) which are adjacent to each other and define the pixel unit. The drain electrodes 119 of the two TFTs are respectively connected with the sub-pixel electrode 130 and the sub-pixel electrode 140. For example, when the sub-pixel electrode 130 and the sub-pixel electrode 140 can be configured to be applied with positive and negative voltage data respectively by the two TFTs, image flickering of the liquid crystal display apparatus can be eliminated. By adopting different gate lines to provide gate signals for different sub-pixel electrodes, flexibility of TFT control can be improved, and complete damage to the pixel electrodes when one single gate line is damaged can be prevented, i.e., a certain redundancy capacity is given to the pixel unit. For example, the sub-pixel electrode 130 and the sub-pixel electrode 140 correspond to the same pixel point in the same display image, absolute values of data voltages applied to the sub-pixel electrode 130 and the sub-pixel electrode 140 are equal, but the data voltages respectively are a positive value and a negative value; and for example, the two gate lines 102 are synchronously applied with on and off signals.

In the embodiment, for example, the source electrode and the drain electrode of the TFT can be both arranged on the gate line, and thus, a portion of the gate line 102 is used as the gate electrode of the TFT, and correspondingly, the active layer of the TFT is also overlapped with the portion used as the gate electrode. Namely, the orthographic projections of the source electrode and the drain electrode of the TFT on one main surface (e.g., the upper surface or the lower surface) of the substrate are at least partially positioned in the orthographic projection of the gate line 102 connected with the TFT on the main surface of the substrate. For example, the orthographic projections of the source electrode and the drain electrode of the TFT on one main surface of the substrate are completely positioned within the orthographic projection of the gate line 102 connected with the TFT on the main surface of the substrate. By adopting the structure that the source electrode and the drain electrode of the TFT are arranged on the gate line, the aperture ratio of the pixel electrode can be promoted and display brightness can be improved.

In one embodiment, the same gate line drives the TFTs of all the sub-pixel electrodes in the pixel units on both sides of the gate line. For example, as shown in FIG. 5, when the sub-pixel electrodes on both the sides of the gate line 102 are all sequentially arranged along the extension direction of the gate line 102, the gate electrodes of the TFTs of those sub-pixel electrodes on both the sides of the gate line all can be connected with the gate line. Namely, by adopting the same gate line to drive all the sub-pixel electrodes in the pixel units which are positioned on both sides of the gate line and adjacent to the gate line, energy consumption is reduced, and materials are saved.

In one embodiment, the same gate line only drives the sub-pixel electrodes which are positioned on both the sides of the gate line and adjacent to the gate line. With reference to FIG. 5, a plurality of gate lines 102 and a plurality of data lines 108, which intersect with each other, define a display region (in the drawing, only a portion of the display region is shown) together, and the display region includes a plurality of pixel units. In each pixel unit (shown as the dotted line in the drawing), the sub-pixel electrodes are arranged side by side along the extension direction of the data lines 108. The same gate line 102 only drives the TFTs of the sub-pixel electrodes which are positioned on both the sides of the gate line and adjacent to the gate line. As shown in FIG. 5, the gate line 102 drives one sub-pixel electrode 130 and the other sub-pixel electrode 140 in one pixel unit. Namely, the same gate line 102 simultaneously drives the sub-pixel electrodes positioned on both the sides of the gate line.

In one embodiment, the same gate line only drives the sub-pixel electrode which is positioned on one side of the gate line and adjacent to the gate line. In each pixel unit in the display region of the substrate, two sub-pixel electrodes, for example, are sequentially arranged along the extension direction of the data line, and are side by side mutually. As mentioned above, one gate line only drives the sub-pixel electrode positioned on one side of the gate line and close to the gate line. Namely, the gate electrode of the TFT of one sub-pixel electrode in the pixel unit is connected with one gate line, and the gate electrode of the TFT of the other sub-pixel electrode is connected with the other gate line adjacent to the gate line. By adopting such gate line connection mode, not only can a case that the sub-pixel electrodes of the same row of pixel units are respectively controlled by different gate lines be implemented, but also a case that different rows of pixel units are respectively controlled by different gate lines can be implemented. Therefore, not only is a case that when one gate line is damaged, the same row of pixel units have faults avoided, but also a case that when one gate line is damaged, the pixel units on both sides of the gate line are simultaneously influenced is avoided, so that stability of the pixel structure is further improved.

In one embodiment, the number of the sub-pixel electrodes, for example, is two. In order to avoid a case that a strong electric field is generated between two sub-pixel electrodes separated from each other to influence the display effect, for example, an interval distance between two sub-pixel electrodes is set as 8 to 10 μm. Therefore, not only can image flickering be effectively prevented, but also a display error cannot be generated.

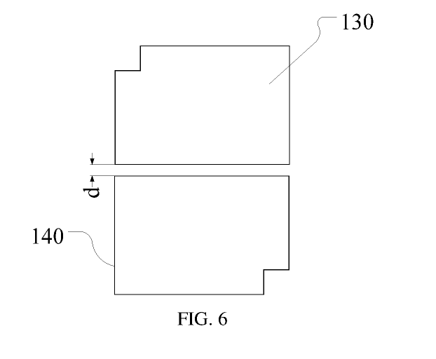

It should be noted that the interval distance between two sub-pixels means a distance between edges of two pixels, which are close to each other, i.e., d marked in FIG. 6.

In one embodiment, two sub-pixel electrodes are plate electrodes or strip electrodes. For example, two sub-pixel electrodes, for example, can also be of other regular or irregular shapes.

Those skilled in the art should understand that according to the present disclosure, the number of the sub-pixel electrodes in one pixel unit is not limited to two, and may also be greater than two, for example, three or four. One TFT is respectively arranged for each sub-pixel electrode. Those skilled in the art can know that in a case that a plurality of sub-pixel electrodes are provided, the source electrode of the TFT of each sub-pixel electrode needs to be connected with the different data line, i.e., the corresponding data lines need to be arranged for the sub-pixel electrodes. As mentioned above, the gate electrodes of the TFTs of a plurality of sub-pixel electrodes, for example, can be connected with the same gate line or respectively connected with different gate lines.

For example, one pixel unit includes three sub-pixel electrodes arranged side by side and three TFTs respectively connected with the three sub-pixel electrodes, and the source electrodes of the three TFTs are connected with different data lines. For example, at the same moment, two of the three sub-pixel electrodes are driven by a positive voltage, and another sub-pixel electrode is driven by a negative voltage; or two sub-pixel electrodes are driven by the negative voltage, and another sub-pixel electrode is driven by the positive voltage.

For example, one pixel unit includes four sub-pixel electrodes arranged side by side and four TFTs respectively connected with the four sub-pixel electrodes, and the source electrodes of the four TFTs are connected with different data lines. For example, at the same moment, two of the four sub-pixel electrodes are driven by a positive voltage, and the other two sub-pixel electrodes are driven by a negative voltage. Certainly, a plurality of sub-pixel electrodes can also be arranged in the same pixel unit, and the sub-pixel electrodes are configured to not only adopt positive voltage driving, but also adopt negative voltage driving. Moreover, for example, the sub-pixel electrodes driven by the positive and negative voltages are alternatively arranged. Those obvious transformations all do not exceed the scope of the present disclosure.

It should be noted that by increasing the number of the sub-pixel electrodes, when those sub-pixel electrodes are simultaneously driven by the positive and negative voltages, flickering of the display image can be further reduced.

The above-mentioned display substrate, for example, may be an array substrate, but the display substrate of the present disclosure is not limited thereto.

By taking a case that one pixel unit includes two sub-pixel electrodes and two sub-pixel electrodes are arranged at an interval along the extension direction of the data line as an example, a preparation method of a display substrate according to the present disclosure will be illustrated, and for example, particularly includes steps of:

Forming a metal layer on a substrate by a sputtering method for example, and then carrying out etching by adopting a first mask to obtain a gate line and a gate electrode connected with the gate line. The metal layer, for example, may include aluminium, aluminium alloy, copper or other suitable materials. After a first mask process is carried out to carry out patterning, the gate line and the gate electrode are formed on the display substrate.

It should be noted that according to the present disclosure, two TFTs are arranged in one pixel unit, and correspondingly, the number of the gate electrodes and the numbers of source electrodes and drain electrodes, which correspond to the gate electrodes, are all two; the source electrode of each TFT is connected with one of two different data lines; and a pattern on the mask should correspond to the structure of the present disclosure.

On the display substrate on which the gate line and the gate electrode are formed, forming an insulating layer so as to use the insulating layer as a gate insulating layer, a material for the insulating layer, for example, including SiNx or SiOx, then forming a semiconductor layer on the insulating layer, and forming an active layer of the TFT by a patterning process, the active layer being arranged on the insulating layer and corresponding to the gate electrode. The active layer can be prepared, for example, by using a photo lithography method, a mask is designed as a pattern of the corresponding active layer, and the active layer in other regions is removed by the photo lithography method for example so as to obtain the active layer corresponding to the gate electrode. A material for forming the active layer, for example, can be amorphous silicon, polycrystalline silicon, an oxide semiconductor (e.g., IGZO) or other suitable materials.

Then, on the substrate on which the active layer is formed, further forming a metal layer. A material of the metal layer, for example, can be aluminium, aluminium alloy, copper or other suitable material. A method for forming the metal layer, for example, may be a Chemical Vapor Deposition (CVD) or sputtering method. A mask with patterns of a source electrode, a drain electrode and a data line is adopted to carry out a photoetching process to pattern the metal layer so as to form the data line intersected with the gate line and the source electrode and the drain electrode which are separated from each other above the active layer. As mentioned above, one pixel unit includes two TFTs, the source electrodes of the two TFTs are respectively connected with two different data lines, and in the step, the adopted mask pattern should correspond thereto.

Then, further forming structures, e.g., a passivation layer, a passivation layer via hole and the like, on the source electrode, the drain electrode and the data line.

Then, continuously covering a transparent conductive layer (e.g., ITO) above the passivation layer, and carrying out photo lithography by a mask with a structure corresponding to the pixel electrode structure of the present disclosure so as to obtain the display substrate structure according to one embodiment of the present disclosure. The mask at least includes patterns corresponding to two sub-pixel electrodes in a first pixel unit, which are separated from each other, and after the mask is subjected to photo lithography exposure, for example, the two formed sub-pixel electrodes separated from each other are sequentially arranged along the extension direction of the data line. The two sub-pixel electrodes are respectively connected to the drain electrode of one of the two TFTs through via holes.

For other embodiments of the present disclosure, the pattern of the mask can be correspondingly changed to carry out photo lithography, which is not repeated herein.

The preparation method of the display substrate according to the present disclosure is not limited to the above-described method.

The present disclosure provides a liquid crystal display apparatus including the display substrate. For example, the display substrate is an array substrate. The display apparatus further includes an opposed substrate, the opposed substrate, for example, is a color filter substrate, and one pixel of the color filter substrate corresponds to two sub-pixel electrodes in the same pixel unit of the display substrate. The liquid crystal display apparatus can effectively reduce flickering of a display image.

For example, the color filter substrate includes pixel units respectively corresponding to a plurality of pixel units on the display substrate. For example, the pixel unit on the color filter substrate and the corresponding pixel unit on the array substrate are opposite to each other in a direction perpendicular to the color filter substrate or the array substrate. Each pixel unit on the color filter substrate includes a color filter of one color, so that light passing through two sub-pixel electrodes of the corresponding pixel unit on the array substrate transmits the color filter.

An embodiment of the present disclosure further provides a driving method of the liquid crystal display apparatus, including: applying voltages to different sub-pixel electrodes of each pixel unit on the display substrate, wherein the voltages applied to different sub-pixel electrodes of each pixel unit are opposite in polarity and equal in absolute value.

In this specification, terms like “first” and “second” are only used to differentiate one entity or operation from another, but are not necessarily used to indicate any practical relationship or order between these entities or operations. Words such as “include” and “comprise” are open-ended expressions, not exclusive of included processes, methods and objects, and denote that other elements also exist. It should be explained that directional or positional relationships shown by terms such as “upper”, “lower” are directional or positional relationships shown as in the drawings, which only means to facilitate description of the invention and simplify the description, but do not indicate or imply that the devices or components must have specific directions, or be constructed or operated in the specific directions, and are not limitative of the invention. Unless expressly stipulated or defined, terms “mounted”, “connected” and “linked” should be broadly understood, for example, they may be fixedly connected, detachably connected, or integrally connected; may be mechanically connected or electrically connected; or may be directly connected, indirectly connected by a medium, or internally communicated between two components. Those skilled in the art can understand specific meanings of the words in the present disclosure according to specific conditions.

The embodiments of the present disclosure, for example, have at least one of the technical effects:

(1) According to the present disclosure, by arranging at least two sub-pixel electrodes in one pixel unit, image flickering can be effectively reduced, and the display effect can be improved.

(2) According to the embodiments of the present disclosure, two thin film transistors in one pixel unit are connected with one gate line or respectively connected with two gate lines, so that the aim of reducing energy consumption or improving driving flexibility can be fulfilled.

(3) According to the embodiments of the present disclosure, by arranging the interval between two sub-pixel electrodes, the display effect can be further improved.

(4) According to the embodiments of the present disclosure, by arranging three or four sub-pixel electrodes in one pixel unit, image flickering can be further reduced, and the display effect can be improved.

The above specific embodiments can be combined mutually, which does not exceed the scope of the present disclosure and can bring a better combination effect.

The foregoing embodiments merely are exemplary embodiments of the disclosure, and not intended to define the scope of the disclosure, and the scope of the disclosure is determined by the appended claims.

The present application claims priority of the Chinese Patent Application No. 201620320070.X filed on Apr. 15, 2016, the disclosure of which are incorporated herein by its reference in its entirety as part of the present application.

1. A display substrate, comprising a plurality of data lines, a plurality of gate lines and a plurality of pixel units, wherein
at least one of the pixel units at least includes two sub-pixel electrodes insulated from each other and two thin film transistors; the two sub-pixel pixels are respectively connected to different thin film transistors in the two thin film transistors, and source electrodes of the two thin film transistors are respectively connected with two different data lines; the two different data lines are configured to apply voltages with opposite polarities and with a same absolute value.

2. (canceled)

3. The display substrate according to claim 1, wherein the two sub-pixel electrodes are respectively positioned in two different regions in the pixel unit.

4. The display substrate according to claim 3, wherein the two sub-pixel electrodes are sequentially arranged in an extension direction of the gate lines.

5. The display substrate according to claim 3, wherein the two sub-pixel electrodes are sequentially arranged in an extension direction of the data lines.

6. The display substrate according to claim 1, wherein gate electrodes of the two thin film transistors are connected to a same gate line or are respectively connected to two different gate lines.

7. The display substrate according to claim 1, wherein an interval distance of the two sub-pixel electrodes is 8 to 10 μm.

8. The display substrate according to claim 1, wherein the two sub-pixel electrodes include plate electrodes or strip electrodes.

9. The display substrate according to claim 1, wherein the at least one pixel unit includes three sub-pixel electrodes which are not in contact with one another and includes three thin film transistors respectively connected with the three sub-pixel electrodes; and source electrodes of the three thin film transistors are respectively connected with different data lines.

10. The display substrate according to claim 1, wherein the at least one pixel unit includes four sub-pixel electrodes which are not in contact with one another and includes four thin film transistors respectively connected with the four sub-pixel electrodes; and source electrodes of the four thin film transistors are respectively connected with different data lines.

11. (canceled)

12. A liquid crystal display apparatus, comprising the display substrate according to claim 1.

13. The liquid crystal display apparatus according to claim 12, further comprising a color filter substrate opposite to the display substrate, the color filter substrate including pixel units respectively corresponding to the plurality of pixel units of the display substrate, and each pixel unit of the color filter substrate including a color filter of one color.

14. A driving method of the liquid crystal display apparatus according to claim 12, comprising:
applying voltages to different sub-pixel electrodes of each pixel unit on the display substrate, wherein the voltages applied to different sub-pixel electrodes of each pixel unit are opposite in polarity and equal in absolute value.

15. (canceled)

16. The liquid crystal display apparatus according to claim 12, wherein the two sub-pixel electrodes are respectively positioned in two different regions in the pixel unit.

17. The liquid crystal display apparatus according to claim 16, wherein the two sub-pixel electrodes are sequentially arranged in an extension direction of the gate lines.

18. The liquid crystal display apparatus according to claim 16, wherein the two sub-pixel electrodes are sequentially arranged in an extension direction of the data lines.

19. The liquid crystal display apparatus according to claim 12, wherein gate electrodes of the two thin film transistors are connected to a same gate line or are respectively connected to two different gate lines.

20. The liquid crystal display apparatus according to claim 12, wherein an interval distance of the two sub-pixel electrodes is 8 to 10 μm.
